(19) United States
(12) Patent Application Publication
(10) Pub. No.: US 2025/0331204 A1
(43) Pub. Date: Oct. 23, 2025

(54) SEMICONDUCTOR DEVICE AND METHOD OF FORMING THE SAME

(71) Applicant: NANYA TECHNOLOGY CORPORATION, New Taipei city (TW)

(72) Inventors: Jyun-Hua YANG, New Taipei City (TW); Chun Lin LU, New Taipei City (TW)

(21) Appl. No.: 18/638,100

(22) Filed: Apr. 17, 2024

(51) Int. Cl. H10D 1/68; H10D 1/00

(52) U.S. Cl. CPC H10D 1/696; H10D 1/042; H10D 1/716

(57) ABSTRACT

A semiconductor device includes a lower electrode layer, a barrier layer, a dielectric layer, and an upper electrode layer. The barrier layer is disposed on the lower electrode layer. The dielectric layer is disposed on the barrier layer. The top electrode layer is disposed on the dielectric layer. The barrier layer is located between the lower electrode layer and the dielectric layer.

### BACKGROUND

### Field of Invention

The present invention relates to a semiconductor device and a method of forming the same.

### Description of Related Art

With the evolution of the scaling of dynamic random-access memory (DRAM) capacitor, a lot of effort was put on searching for new material stacks to overcome the scaling limitations of the current material stack, such as leakage and capacitance. Scaling down of capacitor dielectric is getting difficult to meet target of retention time. Therefore, leakage current in cell capacitance needs to be decreased. Oxygen in dielectric high-k layer diffuses toward titanium nitride (TiN) electrode during subsequent thermal process of following layer, then some vacancies are generated in the dielectric high-k layer. The leakage current may run through oxygen vacancies, which makes capacitor leakage worse. Moreover, the thermal process of following layer leads to a thickness of the TIN electrode and dielectric interface unstable. The unstable interface may contribute to capacitor effective oxygen thickness (EOT) variation. The TIN electrode-dielectric interface leakage and stability of thickness are key points for scaling DRAM.

### SUMMARY

In view of this, one purpose of the present disclosure is to provide a semiconductor device and a method of forming the same can solve the aforementioned problems.

In order to achieve the above objective, according to an embodiment of the present disclosure, a semiconductor device includes a lower electrode layer, a barrier layer, a dielectric layer, and an upper electrode layer. The barrier layer is disposed on the lower electrode layer. The dielectric layer is disposed on the barrier layer. The top electrode layer is disposed on the dielectric layer. The barrier layer is located between the lower electrode layer and the dielectric layer.

In one or more embodiments of the present disclosure, the dielectric layer is separated from the lower electrode layer by the barrier layer.

In one or more embodiments of the present disclosure, the dielectric layer includes a high-k material.

In one or more embodiments of the present disclosure, the barrier layer includes an upper portion and a lower portion. The material of the upper portion is different from a material of the lower portion.

In one or more embodiments of the present disclosure, an electron affinity of the material of the lower portion of the barrier layer is identical to an electron affinity of a material of the lower electrode layer.

In one or more embodiments of the present disclosure, a thickness of the barrier layer is in a range between 5 angstroms and 35 angstroms.

In order to achieve the above objective, according to an embodiment of the present disclosure, a semiconductor device includes a lower electrode layer, a first barrier layer, a second barrier layer, a dielectric layer, and an upper electrode layer. The first barrier layer is disposed on the lower electrode layer. The second barrier layer is disposed on the first barrier layer. The first barrier layer and the second barrier layer form a barrier layer. The dielectric layer is disposed on the second barrier layer. The top electrode layer is disposed on the dielectric layer.

In one or more embodiments of the present disclosure, the dielectric layer is separated from the lower electrode layer by the first barrier layer and the second barrier layer.

In one or more embodiments of the present disclosure, a material of the first barrier layer is different from a material of the second barrier layer.

In one or more embodiments of the present disclosure, an electron affinity of the material of the second barrier layer is identical to an electron affinity of a material of the lower electrode layer.

In one or more embodiments of the present disclosure, a thickness of the first barrier layer is in a range between 4 angstroms and 20 angstroms, and a thickness of the second barrier layer is in a range between 1 angstrom and 20 angstroms.

In one or more embodiments of the present disclosure, a thickness of the barrier layer is in a range between 5 angstroms and 35 angstroms.

In order to achieve the above objective, according to an embodiment of the present disclosure, a method of forming a semiconductor device includes:

forming a lower electrode layer; depositing a first barrier layer on the lower electrode layer; depositing a second barrier layer on the first barrier, so that the first barrier layer and the second barrier layer form a barrier layer; forming a dielectric layer on the second barrier layer; and forming a top electrode layer on the dielectric layer.

In one or more embodiments of the present disclosure, depositing the first barrier layer is performed after forming the lower electrode layer.

In one or more embodiments of the present disclosure, depositing the second barrier layer is performed after depositing the first barrier layer.

In one or more embodiments of the present disclosure, depositing the first barrier layer is performed by an ozone treatment.

In one or more embodiments of the present disclosure, a process temperature of depositing the first barrier layer is in a range between 200 Celsius degrees and 400 Celsius degrees.

In one or more embodiments of the present disclosure, depositing the first barrier layer is performed by using ozone, and the ozone has a density in a range between 50 grams per cubic meter and 500 grams per cubic meter.

In one or more embodiments of the present disclosure, depositing the second barrier layer is performed by using nitrogen plasma.

In one or more embodiments of the present disclosure, a process temperature of depositing the second barrier layer is in a range between 200 Celsius degrees and 600 Celsius degrees.

In summary, in the semiconductor device and the method of forming the same of the present disclosure, since the barrier layer is formed between the lower electrode layer and the dielectric layer, the barrier layer can inhibit ions of the dielectric layer diffuses toward the lower electrode layer, thereby stabilize a thickness of an interface between the dielectric layer and the lower electrode layer. In the semiconductor device and the method of forming the same of the present disclosure, since the barrier layer includes the first barrier layer and the second barrier layer, and the electron affinity of the material of the second barrier layer is identical to the electron affinity of the material of the lower electrode layer, the ions generated from the dielectric layer can be captured in the second barrier layer, thereby avoiding the leakage problem of the semiconductor device. In the semiconductor device and the method of forming the same of the present disclosure, since the material of the first barrier layer is different from the material of the second barrier layer, the thickness of the barrier layer composed of multi-layers with different materials can be less than a thickness of the barrier layer composed of a single layer with a single type of material, thereby lowering the electric resistance of the semiconductor device. Overall, the method of forming the semiconductor device of the present disclosure improves the electrical performance of the entire semiconductor device.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart of a method of forming a semiconductor device in accordance with an embodiment of the present disclosure;

FIG. 2 is a cross-sectional view of an intermediate stage of forming the semiconductor device in accordance with an embodiment of the present disclosure;

FIG. 3 is a cross-sectional view of an intermediate stage of forming the semiconductor device in accordance with an embodiment of the present disclosure;

FIG. 4 is a cross-sectional view of an intermediate stage of forming the semiconductor device in accordance with an embodiment of the present disclosure;

FIG. 5 is a cross-sectional view of an intermediate stage of forming the semiconductor device in accordance with an embodiment of the present disclosure; and

FIG. 6 is a cross-sectional view of an intermediate stage of forming the semiconductor device in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

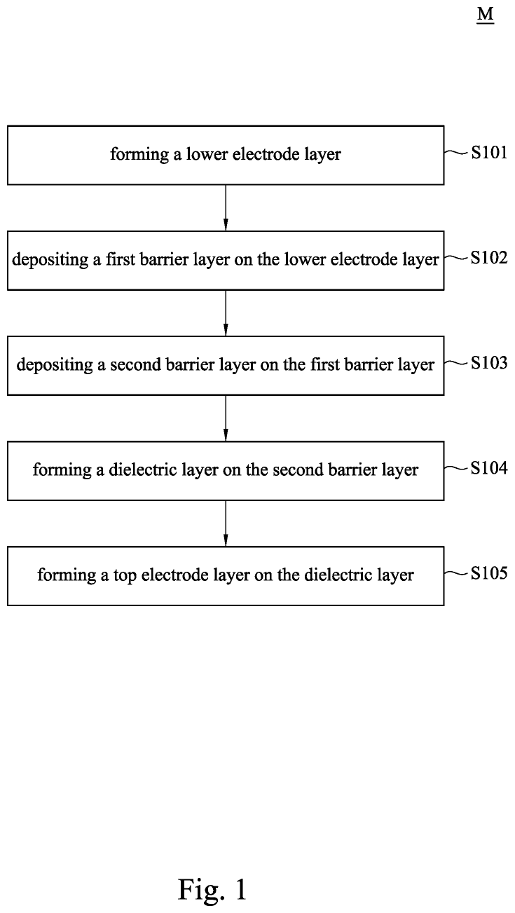

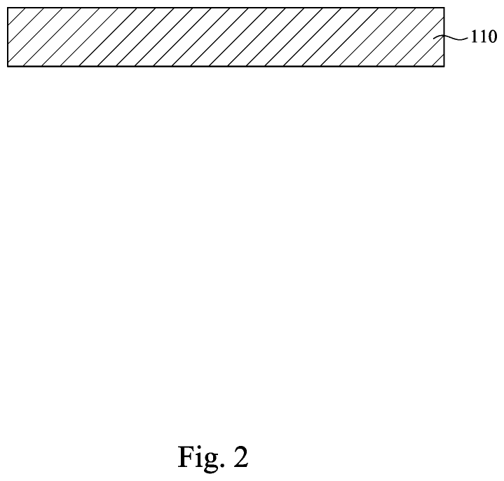

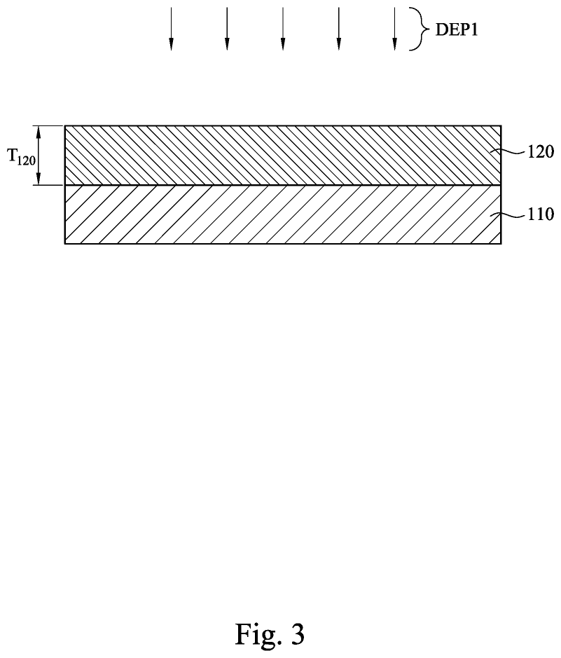

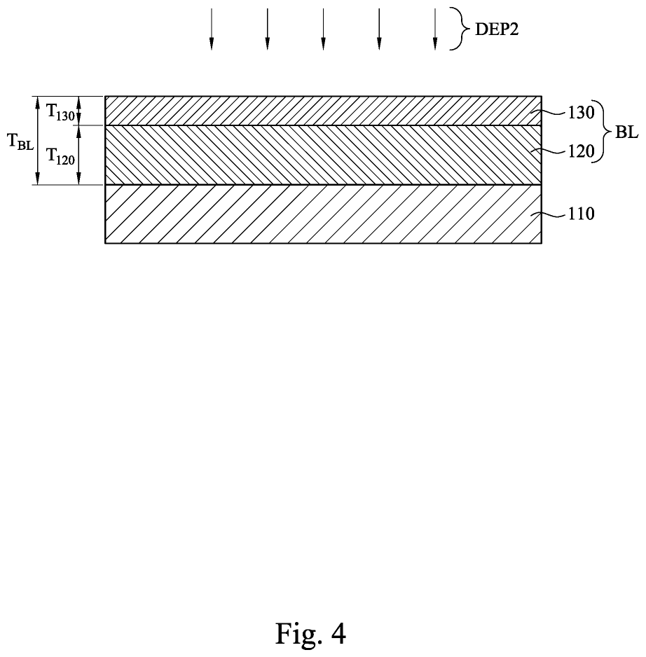

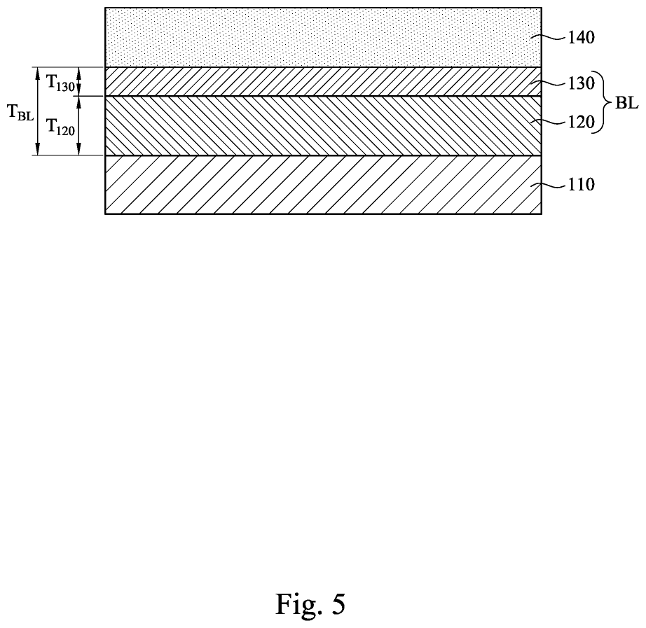

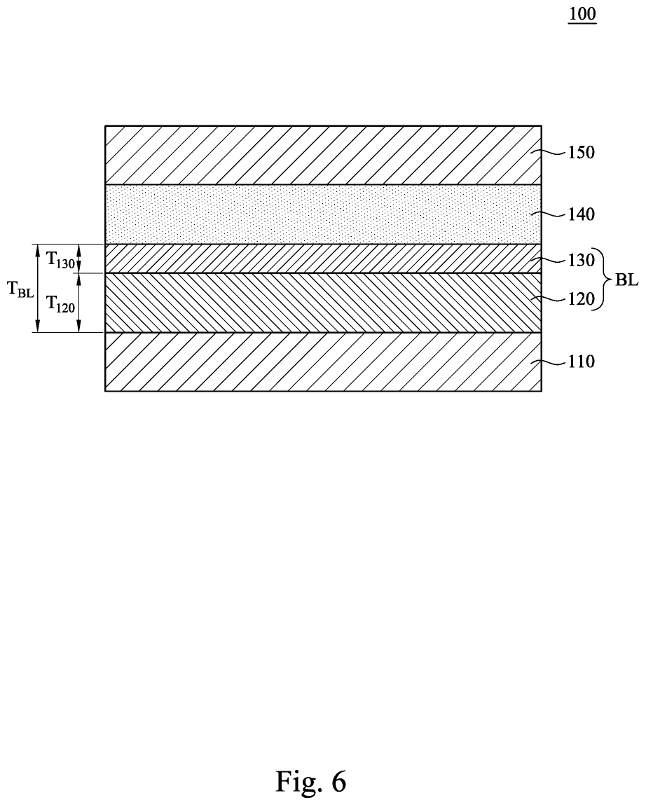

Reference is made to FIG. 1. FIG. 1 is a flow chart of a method M of forming a semiconductor device 100 as shown in FIG. 6 in accordance with an embodiment of the present disclosure. The method M shown in FIG. 1 includes a step S101, a step S102, a step S103, a step S104, and a step S105. Please refer to FIG. 1 and FIG. 2 for better understanding the step S101, refer to FIG. 1 and FIG. 3 for better understanding the step S102, refer to FIG. 1 and FIG. 4 for better understanding the step S103, refer to FIG. 1 and FIG. 5 for better understanding the step S104, and refer to FIG. 1 and FIG. 6 for better understanding the step S105.

Step S101, step S102, step S103, step S104, and step S105 are described in detail below.

In step S101, a lower electrode layer 110 is formed.

Reference is made to FIG. 1 and FIG. 2. FIG. 2 is a cross-sectional view of an intermediate stage of forming a semiconductor device 100 in accordance with an embodiment of the present disclosure. As shown in FIG. 2, in this embodiment, the lower electrode layer 110 is provided. In some embodiments, the lower electrode layer 110 is configured as a lower electrode of the semiconductor device 100 shown in FIG. 6. In some embodiments, the semiconductor device 100 is configured as a capacitor of a dynamic random-access memory (DRAM).

In some embodiments, the lower electrode layer 110 may be conductive material. In some embodiments, the lower electrode layer 110 may be metallic material. In some embodiments, the lower electrode layer 110 may include a material, such as titanium nitride (TiN), or the like. However, any suitable material may be utilized.

In some embodiments, the lower electrode layer 110 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the lower electrode layer 110.

In step S102, a first barrier layer 120 is deposited.

Reference is made to FIG. 1 and FIG. 3. FIG. 3 is a cross-sectional view of an intermediate stage of forming the semiconductor device 100 in accordance with an embodiment of the present disclosure. As shown in FIG. 3, in this embodiment, the first barrier layer 120 is formed on the lower electrode layer 110. In other words, depositing the first barrier layer 120 is performed after forming the lower electrode layer 110. As shown in FIG. 3, the first barrier layer 120 is formed by a deposition process DEP1. In some embodiments, the first barrier layer 120 has a thickness T120.

In some embodiments, the thickness T120 of the first barrier layer 120 is in a range between about 4 angstroms (Å) and about 20 angstroms (Å), but the present disclosure is not limited thereto. In some embodiment in which the thickness T120 of the first barrier layer 120 is less than about 4 angstroms, the first barrier layer 120 may not able to inhibit ions diffusing toward the lower electrode layer 110, thereby causing the leakage problem. In some embodiment in which the thickness T120 of the first barrier layer 120 is greater than about 20 angstroms, the electrical resistance of the semiconductor device 100 may not be satisfying, thereby reducing the overall capacitance of the semiconductor device 100.

In some embodiments, the first barrier layer 120 may include a material, such as titanium oxide (TiO₂), or the like. However, any suitable material may be utilized.

In some embodiments, the first barrier layer 120 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the first barrier layer 120.

In some embodiments, the first barrier layer 120 may be deposited by the deposition process DEP1 using an ozone treatment. The present disclosure is not intended to limit the methods of forming the first barrier layer 120.

In some embodiments, a process temperature of the deposition process DEP1 of depositing the first barrier layer 120 is in a range between about 200 Celsius degrees (° C.) and about 400 Celsius degrees (° C.). However, the present disclosure is not limited thereto.

In some embodiments, the first barrier layer 120 may be deposited by the deposition process DEP1 using an ozone. In some embodiments, the ozone has a density in a range between about 50 grams per cubic meter (g/m³) and about 500 grams per cubic meter (g/m³). However, the present disclosure is not limited thereto.

In step S103, a second barrier layer 130 is deposited.

Reference is made to FIG. 1 and FIG. 4. FIG. 4 is a cross-sectional view of an intermediate stage of forming the semiconductor device 100 in accordance with an embodiment of the present disclosure. As shown in FIG. 4, in this embodiment, the second barrier layer 130 is formed on the first barrier layer 120. As shown in FIG. 4, the second barrier layer 130 is formed by a deposition process DEP2. In some embodiments, the second barrier layer 130 has a thickness T130. As shown in FIG. 4, in some embodiments, depositing the second barrier layer 130 is performed after depositing the first barrier layer 120, so that a barrier layer BL is formed. More specifically, the barrier layer BL includes an upper portion (e.g., the second barrier layer 130) and a lower portion (e.g., the first barrier layer 120). In some embodiments, a material of the upper portion is different from a material of the lower portion. Namely, a material of the first barrier layer 120 is different from a material of the second barrier layer 130. In some embodiments, an electron affinity of the material of the lower portion of the barrier layer BL is identical to an electron affinity of the material of the lower electrode layer 110. Namely, an electron affinity of the material of the first barrier layer 120 is identical to an electron affinity of the material of the lower electrode layer 110. In some embodiments, the barrier layer BL has a thickness TBL. In some embodiments, the thickness TBL of the barrier layer BL is substantially a sum of the thickness T120 of the first barrier layer 120 and the thickness T130 of the second barrier layer 130.

In some embodiments, the thickness T130 of the second barrier layer 130 is in a range between about 1 angstrom (Å) and about 20 angstroms (Å), but the present disclosure is not limited thereto. In some embodiment in which the thickness T130 of the second barrier layer 130 is less than about 1 angstrom, the second barrier layer 130 may not able to inhibit ions diffusing toward the first barrier layer 120 and the lower electrode layer 110, thereby causing the leakage problem. In some embodiment in which the thickness T130 of the second barrier layer 130 is greater than about 20 angstroms, the electrical resistance of the semiconductor device 100 may not be satisfying, thereby reducing the overall capacitance of the semiconductor device 100.

In some embodiments, the thickness T130 of the second barrier layer 130 may be less than the thickness T120 of the first barrier layer 120. However, the present disclosure is not limited thereto.

In some embodiments, the thickness T120 of the first barrier layer 120 may be preferred about 8.5 angstroms. In some embodiments, the thickness T130 of the second barrier layer 130 may be preferred about 1.5 angstroms. However, the present disclosure is not limited thereto.

In some embodiments, the thickness TBL of the barrier layer BL is in a range between about 5 angstroms (Å) and about 35 angstroms (Å), but the present disclosure is not limited thereto. In some embodiment in which the thickness TBL of the barrier layer BL is less than about 5 angstroms, the barrier layer BL may not able to inhibit ions diffusing toward the lower electrode layer 110, thereby causing the leakage problem. In some embodiment in which the thickness TBL of the barrier layer BL is greater than about 35 angstroms, the electrical resistance of the semiconductor device 100 may not be satisfying, thereby reducing the overall capacitance of the semiconductor device 100.

In some embodiments, the second barrier layer 130 may include a material, such as titanium oxynitride (TION), or the like. However, any suitable material may be utilized.

In some embodiments, the second barrier layer 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the second barrier layer 130.

In some embodiments, the second barrier layer 130 may be deposited by the deposition process DEP2 using a nitrogen plasma. The present disclosure is not intended to limit the methods of forming the second barrier layer 130.

In some embodiments, a process temperature of the deposition process DEP2 of depositing the second barrier layer 130 is in a range between about 200 Celsius degrees (° C.) and about 600 Celsius degrees (C.). However, the present disclosure is not limited thereto.

In step S104, the dielectric layer 140 is formed.

Reference is made to FIG. 1 and FIG. 5. FIG. 5 is a cross-sectional view of an intermediate stage of forming the semiconductor device 100 in accordance with an embodiment of the present disclosure. As shown in FIG. 5, in this embodiment, the dielectric layer 140 is disposed on the barrier layer BL. In some embodiments, the dielectric layer 140 is disposed on the second barrier layer 130. As shown in FIG. 5, the barrier layer BL is located between the lower electrode layer 110 and the dielectric layer 140. In other words, the dielectric layer 140 is separated from the lower electrode layer 110 by the barrier layer BL. In some embodiments, the first barrier layer 120 and the second barrier layer 130 is located between the lower electrode layer 110 and the dielectric layer 140. Namely, the dielectric layer 140 is separated from the lower electrode layer 110 by the first barrier layer 120 and the second barrier layer 130.

In some embodiments, the dielectric layer 140 may include a high-k material. In some embodiments, the dielectric layer 140 may include an oxide material. In some embodiments, the dielectric layer 140 may include a material, such as zirconium oxide (ZrO₂), hafnium oxide (HfO₂), aluminum oxide (Al₂O₃), silicon oxide (SiO₂), or the like. However, any suitable material may be utilized.

In some embodiments, the dielectric layer 140 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the dielectric layer 140.

As shown in FIG. 4, in some embodiments, step S104 is performed after step S103. In some embodiments, forming the dielectric layer 140 is performed after forming the barrier layer BL. In other words, forming the dielectric layer 140 is performed after depositing the second barrier layer 130.

In some embodiments in which the dielectric layer 140 composed of high-k oxide, oxygen in the dielectric layer 140 diffuses toward the lower electrode layer 110 during subsequent processes (e.g., thermal process), then some vacancies are generated in the dielectric layer 140. The barrier layer BL can inhibit the oxygen diffusing toward the lower electrode layer 110 due to the similar (or, identical, in some embodiments) electron affinity between the barrier layer BL (especially, the first barrier layer 120) and the lower electrode layer 110. In step S105, an upper electrode layer 150 is formed.

Reference is made to FIG. 1 and FIG. 6. FIG. 6 is a cross-sectional view of an intermediate stage of forming a semiconductor device 100 in accordance with an embodiment of the present disclosure. As shown in FIG. 6, in this embodiment, the upper electrode layer 150 is formed, such that the semiconductor device 100 is formed. More specifically, the upper electrode layer 150 is disposed on the dielectric layer 140. The dielectric layer 140 is disposed between the upper electrode layer 150 and the lower electrode layer 110, thereby forming a capacitor. In some embodiments, the upper electrode layer 150 is configured as an upper electrode of the semiconductor device 100 shown in FIG. 6.

In some embodiments, the upper electrode layer 150 may be conductive material. In some embodiments, the upper electrode layer 150 may be metallic material. In some embodiments, the upper electrode layer 150 may include a material, such as titanium nitride (TIN), or the like. However, any suitable material may be utilized.

In some embodiments, the upper electrode layer 150 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the upper electrode layer 150.

By performing the method M shown in FIG. 1 of the present disclosure, the semiconductor device 100 with better electrical performance may be formed.

Based on the above discussions, it can be seen that in the semiconductor device and the method of forming the same of the present disclosure, since the barrier layer is formed between the lower electrode layer and the dielectric layer, the barrier layer can inhibit ions of the dielectric layer diffuses toward the lower electrode layer, thereby stabilize a thickness of an interface between the dielectric layer and the lower electrode layer. In the semiconductor device and the method of forming the same of the present disclosure, since the barrier layer includes the first barrier layer and the second barrier layer, and the electron affinity of the material of the second barrier layer is identical to the electron affinity of the material of the lower electrode layer, the ions generated from the dielectric layer can be captured in the second barrier layer, thereby avoiding the leakage problem of the semiconductor device. In the semiconductor device and the method of forming the same of the present disclosure, since the material of the first barrier layer is different from the material of the second barrier layer, the thickness of the barrier layer composed of multi-layers with different materials can be less than a thickness of the barrier layer composed of a single layer with a single type of material, thereby lowering the electric resistance of the semiconductor device.

Overall, the method of forming the semiconductor device of the present disclosure improves the electrical performance of the entire semiconductor device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a lower electrode layer;
a barrier layer disposed on the lower electrode layer;
a dielectric layer disposed on the barrier layer; and
a top electrode layer disposed on the dielectric layer, wherein the barrier layer is located between the lower electrode layer and the dielectric layer.

2. The semiconductor device of claim 1, wherein the dielectric layer is separated from the lower electrode layer by the barrier layer.

3. The semiconductor device of claim 1, wherein the dielectric layer comprises a high-k material.

4. The semiconductor device of claim 1, wherein the barrier layer comprises an upper portion and a lower portion, and a material of the upper portion is different from a material of the lower portion.

5. The semiconductor device of claim 1, wherein an electron affinity of a material of the lower portion of the barrier layer is identical to an electron affinity of a material of the lower electrode layer.

6. The semiconductor device of claim 1, wherein a thickness of the barrier layer is in a range between 5 angstroms (Å) and 35 angstroms (Å).

7. A semiconductor device, comprising:
a lower electrode layer;
a first barrier layer disposed on the lower electrode layer;
a second barrier layer disposed on the first barrier layer, wherein the first barrier layer and the second barrier layer form a barrier layer;
a dielectric layer disposed on the second barrier layer; and
a top electrode layer disposed on the dielectric layer.

8. The semiconductor device of claim 7, wherein the dielectric layer is separated from the lower electrode layer by the first barrier layer and the second barrier layer.

9. The semiconductor device of claim 7, wherein a material of the first barrier layer is different from a material of the second barrier layer.

10. The semiconductor device of claim 7, wherein an electron affinity of a material of the second barrier layer is identical to an electron affinity of a material of the lower electrode layer.

11. The semiconductor device of claim 7, wherein a thickness of the first barrier layer is in a range between 4 angstroms (Å) and 20 angstroms (Å), and a thickness of the second barrier layer is in a range between 1 angstrom (Å) and 20 angstroms (Å).

12. The semiconductor device of claim 7, wherein a thickness of the barrier layer is in a range between 5 angstroms (Å) and 35 angstroms (Å).

13. A method of forming a semiconductor device, comprising:
forming a lower electrode layer;
depositing a first barrier layer on the lower electrode layer;
depositing a second barrier layer on the first barrier, so that the first barrier layer and the second barrier layer form a barrier layer;
forming a dielectric layer on the second barrier layer; and
forming a top electrode layer on the dielectric layer.

14. The method of claim 13, wherein depositing the first barrier layer is performed after forming the lower electrode layer.

15. The method of claim 13, wherein depositing the second barrier layer is performed after depositing the first barrier layer.

16. The method of claim 13, wherein depositing the first barrier layer is performed by an ozone treatment.

17. The method of claim 13, wherein a process temperature of depositing the first barrier layer is in a range between 200 Celsius degrees (° C.) and 400 Celsius degrees (° C.).

18. The method of claim 13, wherein depositing the first barrier layer is performed by using ozone, and the ozone has a density in a range between 50 grams per cubic meter (g/m³) and 500 grams per cubic meter (g/m³).

19. The method of claim 13, wherein depositing the second barrier layer is performed by using nitrogen plasma.

20. The method of claim 13, wherein a process temperature of depositing the second barrier layer is in a range between 200 Celsius degrees (° C.) and 600 Celsius degrees (° C.).
